(19) United States
(12) Patent Application Publication
(10) Pub. No.: US 2026/0300601 A1
(43) Pub. Date: Oct. 1, 2026

(54) TRAINING A MACHINE LEARNING MODEL FOR INCREMENTAL TOPOLOGY SYNTHESIS

(71) Applicant: ARTERIS, INC., Campbell, CA (US)

(72) Inventors: Amir CHARIF, Paris (FR); Ugo LECERF, Paris (FR); Donatello CONTE, Paris (FR)

(73) Assignee: ARTERIS, INC., Campbell, CA (US)

(21) Appl. No.: 19/270,429

(22) Filed: Jul. 15, 2025

Related U.S. Application Data
(63) Continuation-in-part of application No. 19/227,528, filed on Jun. 4, 2025.
Application No. 19/227,528 is a continuation of application No. 19/095,082, filed on Mar. 31, 2025.

(51) Int. Cl. G06F 30/392

(52) U.S. Cl. CPC G06F 30/392

(57) ABSTRACT

A computer system includes a processing unit and computer memory encoded with code. The code, when executed by the processing unit, causes the computer system to elect a source and a set of destinations in a network-on-chip (NoC) topology; and incrementally add new connections to the NoC topology, one connection at a time until the source is connected to the destinations. Adding a new connection includes using a trained machine learning model (or a large language model) to receive a current state of the NoC topology and suggest a new state including a new connection. If valid, the new connection is added to the current state.

### CROSS REFERENCE TO RELATED APPLICATION

This application is a continuation-in-part of U.S. application Ser. No. 19/227,528 filed on Jun. 4, 2025 and titled INCREMENTAL TOPOLOGY SYNTHESIS WITH LOOKAHEAD FOR A NETWORK-ON-CHIP by Amir CHARIF. U.S. application Ser. No. 19/227,528 is a continuation of U.S. application Ser. No. 19/095,082 filed on Mar. 31, 2025 and titled INCREMENTAL TOPOLOGY SYNTHESIS FOR A NETWORK-ON-CHIP by Amir CHARIF, the entire disclosures of which are incorporated herein by reference.

### FIELD

The present technology is in the field of electronic computer aided design of electronic systems, and more specifically, to electronic topology synthesis of a network-on-chip.

### BACKGROUND

Network on a chip (NoC) technology is being used at many semiconductor companies to support an ever-increasing number of cores on a single chip and satisfy a demand for ever-increasing processing power related to artificial intelligence (AI) and other applications. A NoC is superior to old point-to-point connectivity by way of a more scalable communication architecture that makes use of packet transmissions.

A NoC topology refers to a general layout of NoC elements (e.g., network interface units, buffers, switches, pipes, probes, firewalls, and adapters) and electrical connections between the NoC elements. During design of a NoC, multiple iterations of the NoC topology may be generated until certain criteria are satisfied.

### SUMMARY

In accordance with various embodiments and aspects herein, a computer system includes a processing unit and computer memory encoded with code. The code, when executed by the processing unit, causes the computer system to elect a source and a set of destinations in a network-on-chip (NoC) topology; and incrementally add new connections to the NoC topology, one connection at a time until the source is connected to the destinations. Adding a new connection includes using a trained machine learning model to receive a current state of the NoC topology and suggest a new state including a new connection. If valid, the new connection is added to the current state.

In accordance with various embodiments and aspects herein, a computer-implemented method of NoC synthesis includes using a trained machine learning model to generate a coarse-level NoC topology, including incrementally adding new connections to the coarse-level topology until at least one source is connected to a corresponding set of destinations. The machine learning model is trained to receive a current state of the NoC topology and generate a new state including a new connection. The computer-implemented method further includes identifying redundant switches and redundant connections in the coarse-level NoC topology; and using the identified switches and identified connections as feedback to fine-tune the machine learning model.

In accordance with various embodiments and aspects herein, a computer-implemented method of designing a NoC includes accessing a multitude of traces generated for different NoC designs. Each trace describes an intermediate state of a NoC topology after a new connection from a source to a destination is added. The method further includes identifying redundant switches and redundant connections in the traces and tagging the redundant switches and the redundant connections in the traces; and training a machine learning model on the traces to predict a next state of a NoC topology given its current state such that the next state avoids redundant switches and redundant connections.

### BRIEF DESCRIPTION OF THE DRAWINGS

In order to understand the invention more fully, a reference is made to the accompanying drawings. The invention is described in accordance with the aspects and embodiments in the following description with reference to the drawings or figures (FIG.), in which like numbers represent the same or similar elements. Understanding that these drawings are not to be considered limitations in the scope of the invention, the presently described aspects and embodiments and the presently understood best mode of the invention are described with additional detail through the use of the accompanying drawings.

FIG. 1 shows certain features of an electronic system including a NoC.

FIG. 2 shows an overview of a NoC design process in accordance with various aspects and embodiments herein.

FIG. 3 shows an incremental topology synthesis method in accordance with various aspects and embodiments herein.

FIGS. 4A, 4B, 4C, 4D and 4E illustrate a simple example in which an initial topology is synthesized according to the method of FIG. 3.

FIG. 5 shows an incremental topology synthesis method with lookahead in accordance with various aspects and embodiments herein.

FIGS. 6A, 6B, 6C, and 6D illustrate a simple example in which an initial topology is synthesized according to the method of FIG. 5.

FIG. 7 shows a tree representation of a simple example of different routing options during incremental topology synthesis with lookahead in accordance with various aspects and embodiments herein.

FIG. 8 shows a method of identifying and removing redundant switches and redundant connections in accordance with various aspects and embodiments herein.

FIG. 9 shows a computer system including code for performing incremental topology synthesis in accordance with various aspects and embodiments herein.

FIG. 10 shows a computer system including a trained machine learning model and code for performing incremental NoC topology synthesis in accordance with various aspects and embodiments herein.

FIG. 11 shows a method of using a trained machine learning model to perform incremental NoC topology synthesis in accordance with various aspects and embodiments herein.

FIG. 12 shows a method of training a machine learning model to perform incremental NoC topology synthesis in accordance with various aspects and embodiments herein.

### DETAILED DESCRIPTION

The following describes various examples of the present technology that illustrate various aspects and embodiments of the invention. Generally, examples can use the described aspects in any combination. All statements herein reciting principles, aspects, and embodiments as well as specific examples thereof, are intended to encompass both structural and functional equivalents thereof. The examples provided are intended as non-limiting examples. Additionally, it is intended that such equivalents include both currently known equivalents and equivalents developed in the future, i.e., any elements developed that perform the same function, regardless of structure.

It is noted that, as used herein, the singular forms “a,” “an” and “the” include plural referents unless the context clearly dictates otherwise. Reference throughout this specification to “one embodiment,” “an embodiment,” “certain embodiment,” “various embodiments,” or similar language means that a particular aspect, feature, structure, or characteristic described in connection with the embodiment is included in at least one embodiment of the invention.

Thus, appearances of the phrases “in one embodiment,” “in at least one embodiment,” “in an embodiment,” “in certain embodiments,” and similar language throughout this specification may, but do not necessarily, all refer to the same embodiment or similar embodiments. Furthermore, aspects and embodiments of the invention described herein are merely exemplary, and should not be construed as limiting of the scope or spirit of the invention as appreciated by those of ordinary skill in the art. The disclosed invention is effectively made or used in any embodiment that includes any novel aspect described herein.

All statements herein reciting principles, aspects, and embodiments of the invention are intended to encompass both structural and functional equivalents thereof. It is intended that such equivalents include both currently known equivalents and equivalents developed in the future. Furthermore, to the extent that the terms “including”, “includes”, “having”, “has”, “with”, or variants thereof are used in either the detailed description and the claims, such terms are intended to be inclusive in a similar manner to the term “comprising.”

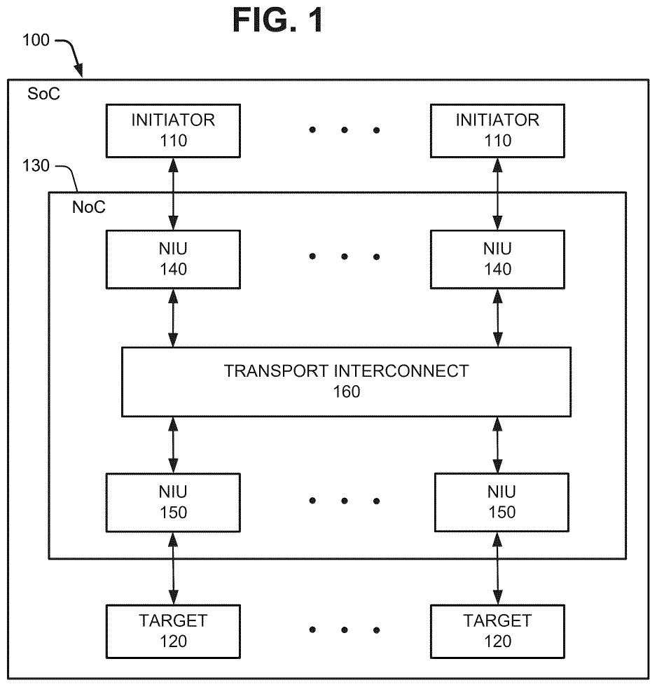

Reference is made to FIG. 1, which illustrates an electronic system. By way of example, the electronic system is a system on chip (SoC) 100. The SoC 100 includes a plurality of initiators 110 and targets 120. Examples of the initiators 110 include central processing units (CPUs), graphics processing units (GPUs), video cards, accelerators, and direct memory access (DMA) controllers. Examples of the targets 120 include volatile memory, persistent memory, and peripherals.

The SoC 100 further includes a network-on-chip (NoC) 130. The NoC 130 sends request transactions from an initiator 110 to one or more targets 120 using industry-standard protocols. A request transaction may include an address of the target 120. The NoC 130 decodes the address and transports the request transaction. The target 120 handles the request transaction and may send a response transaction, which is transported back to the initiator 110 via the NoC 130.

The NoC 130 includes a plurality of network interface units (NIUs) 140 and 150 and a transport interconnect 160. Those NIUs 140 that interface with initiators 110 are referred to as initiator NIUs 140, and those NIUs 150 that interface with targets 120 are referred to as target NIUs 150. Each initiator 110 is coupled to the transport interconnect 160 via a corresponding initiator NIU 140. Each target 120 is coupled to the transport interconnect 160 via a corresponding target NIU 150.

Each NIU 140 is configured to convert the protocol used by its corresponding initiator 110 into a transport protocol used inside the NoC 130. Each NIU 150 is configured to convert the protocol used by the NoC 130 into a transport protocol used its corresponding target 120. The transport protocol used by the NoC 130 is typically based on the transmission of packets.

The transport interconnect 160 includes NoC elements such as switches, adapters, and buffers for transporting packets between the NIUs 140 and 150. Switches may be used to route flows of traffic between source and destinations. Adapters may be used to deal with various conversions between data width, clock and power domains. Buffers may be used to insert pipelining elements to span long distances, or to store packets to deal with rate adaptation between fast senders and slow receivers or vice-versa.

In general, the NoC 130 is highly configurable. Certain NoC components such as the NIUs 140 and 150 and switches may have many different possible configurations. Other NoC components such as buffers may have relatively fewer possible configurations.

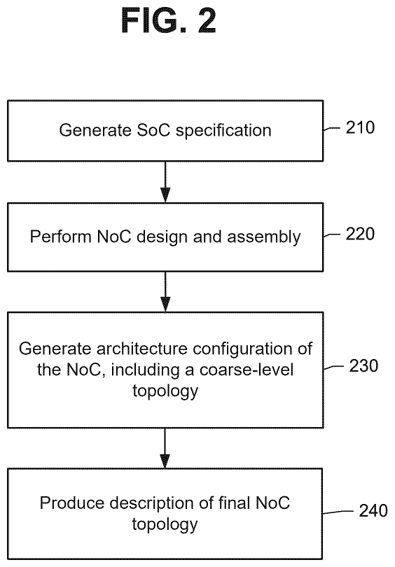

Reference is made to FIG. 2, which illustrates a general method of designing a NoC. At block 210, an SoC specification is generated. The specification provides a chip definition, technology, domains and layout for the SoC. The SoC layout may include the locations of initiators and targets. The specification also defines the real estate for the NoC and other NoC constraints.

At block 220, NoC design and assembly are performed. Intellectual property (IP) blocks are selected from a NoC library, and the selected IP is instantiated. In addition, IP connection and assembly, sockets configuration, and end-to-performance capture may be performed. This stage produces a NoC specification that defines SoC IPs and their related sockets and protocols, along with the communication flows between initiators and targets, and memory maps.

At block 230, an architecture configuration of the NoC is generated. A coarse-level NoC topology is generated in accordance with a method herein. Then the coarse-level topology is modified. Switches, buffers, firewalls, pipelines and rate adapters are added to the topology. Power, Performance and Area (PPA) tradeoffs may be performed (unit duplication is decided together with size of buffers in switches for example). A loop from block 230 back to block 220 helps in finalizing the architecture configuration by changing the settings of parameters, changing connectivity schemes (e.g., from a mesh to crossbar or modified mesh), enabling of safety through unit duplication, etc.

A NoC design may have to satisfy different performance requirements, such as connectivity and latency between source and destination, frequency of various elements, maximum area available for NoC logic and its associated routing, minimum throughput between sources and destinations, power consumption requirements, and position on the chip floorplan. Multiple iterations of the NoC topology may be generated until the different performance requirements are satisfied.

At block 240, a final NoC topology description is produced, for instance, in a computer-readable file or done through a user interface, in graphical or textual form. In accordance with some aspects of the invention, the description may be register-transfer level (RTL). The description may be stored in computer memory, ready for use by software.

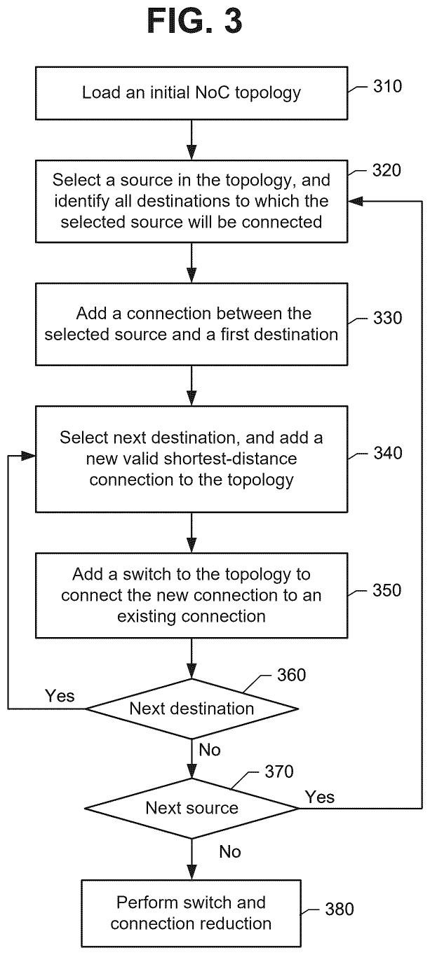

Reference is made to FIG. 3, which illustrates a method of automatically generating a coarse-level topology of a NoC. In general, electrical connections are made between sources and destinations to facilitate electrical communication between the sources and destinations. Each connection may include one or more wires. For example, a 32 bit connection between may include 32 individual wires in parallel. Routing of the connections may be rectilinear.

At block 310, an initial NoC topology is loaded. The initial NoC topology may include at least initiator ports and several target ports. The initial topology may also include NIUs at the initiator and target ports The initial topology may further include existing transport interconnect components (e.g., switches) and connections.

A source may include an initiator, and a destination may include a target. However, sources and destinations as used herein are not so limited. Sources and destinations may include internal NoC elements. For example, if an existing NoC component will be rerouted, that existing component may be treated as a source or a destination.

User inputs and relevant information from the specification may also be loaded. For instance, the specification may identify all destinations to which each source will be connected.

At block 320, a source in the topology is selected, and all destinations to which the selected source will be connected are identified. A user input may specify the source that is selected, or the source may be selected automatically. The NoC specification may be used to identify the destinations. The destinations may be ordered. Let N be the total number of destinations, and let D={D1, . . . , DN} be the set of destinations after ordering, wherein at least one destination is proximal or closest to the source. As a first example, the ordering is specified by a user input. As a second example, the destinations are sorted by distance from the selected source. The distances may be straight-line distances.

At block 330, a connection between the selected source and the first destination D1 is added to the topology.

At block 340, the next destination in set D is selected, and a new connection is added to the topology. The new connection is a new shortest valid connection from the selected destination to an existing connection in the topology. A new connection is considered valid if it follows constraints, is deadlock free, etc. A deadlock refers to a state that can arise when nodes along a path are in a circular “wait” and prevent each other from accessing the resources and from transmitting messages.

At block 350, a switch is added to the topology to connect the new connection to the existing connection. For example, the existing connection may be split into sub-connections, and the switch is inserted and coupled to the sub-connections and the new connection.

The functions at blocks 340 and 350 are automatically repeated until all of the destinations in set D have been connected to the selected source (block 360). In the alternative, a user input may specify the next destination, and the functions at blocks 340 and 350 are repeated for the specified destination.

If another source is selected (block 370), control is returned to block 320. The selection may be made automatically or by user inputs.

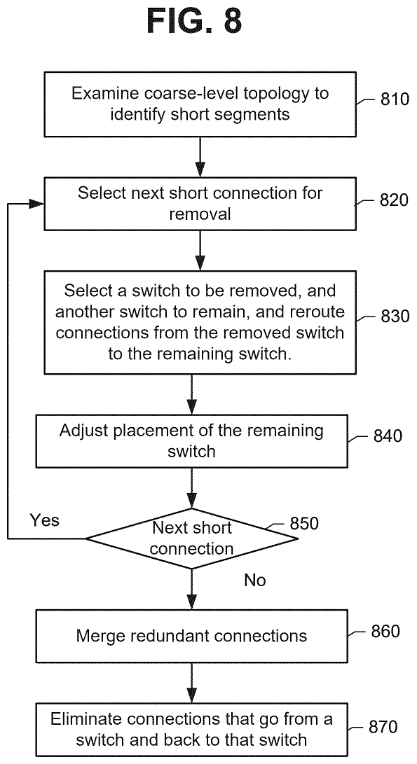

At block 380, the topology may be further refined by reducing the number of switches and connections. An example of a reduction method is illustrated in FIG. 8. Another example is described in assignee's U.S. Pat. No. 11,655,776.

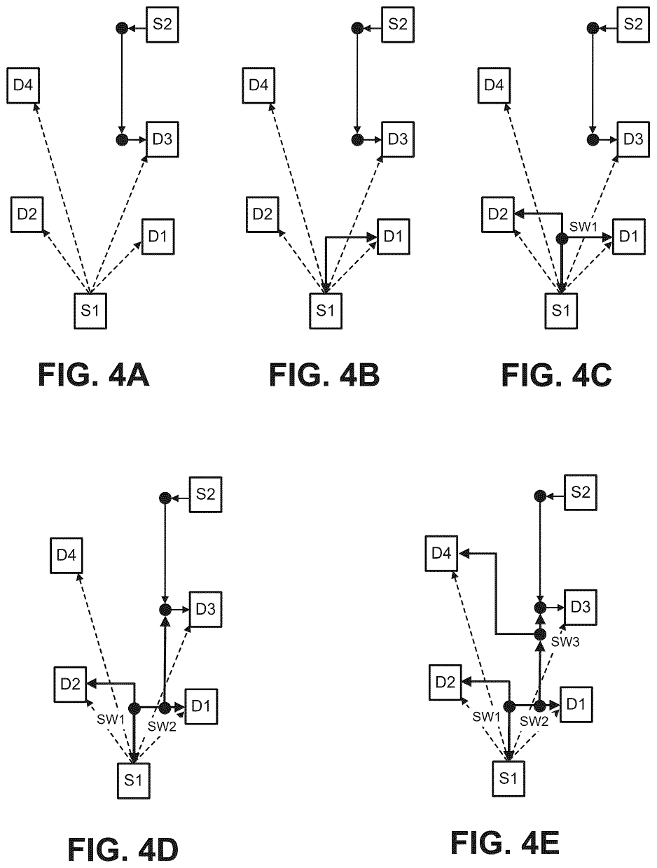

FIGS. 4A, 4B, 4C, 4D and 4E illustrate a simple example in which an initial topology is incrementally synthesized according to blocks 310-370 of the method of FIG. 3. FIG. 4A shows an initial NoC topology that is loaded: a source S1, and a set D of four destinations in the following order: a first destination D1, a second destination D2, a third destination D3 and a fourth destination D4. The initial topology also has existing NoC components from an earlier topology: a second source S2 that is already connected to the third destination D3 by a connection S2-D3. The method of FIG. 3 will be used to connect the first source S1 to the first, second, third and fourth destinations D1, D2, D3 and D4.

FIG. 4B shows the NoC topology after a first incremental modification. A first connection from the first source S1 to first destination D1 is added to the topology.

FIG. 4C shows the NoC topology after a second incremental modification. The second destination D2 is selected for the next connection. A second connection connecting the second destination D2 to the first connection is added to the topology such that the second connection follows the shortest valid path to the first connection. A switch SW1 is added to the topology to connect the second connection to the first connection.

FIG. 4D shows the NoC topology after a third incremental modification. The third destination D3 is selected for the next connection. A third connection and a second switch SW2 are added to the topology. The third connection connects the third destination D3 to the first connection via the second switch SW2. The third connection extends along the shortest valid path.

FIG. 4E shows the NoC topology after a fourth incremental modification. The fourth destination D4 is the last destination in set D. A fourth connection connects the fourth destination D4 to the third connection via a third switch SW3.

Thus, the method of FIG. 3 automatically modifies the NoC topology, one connection at a time. This reduces processing burden and reduces the time to generate a NoC architecture configuration.

The method creates the fewest connections at the time a selected source is connected to a selected destination. For example, when connecting the first source S1 to the third destination D3, the chosen configuration is one that creates the least extra connections at the time the connections are added to the topology. The fourth connection that connects the first source S1 to the fourth destination D4 deviates quite a bit from a dedicated connection that goes straight to the fourth destination. The deviation could be minimized, but at the cost of creating more connections.

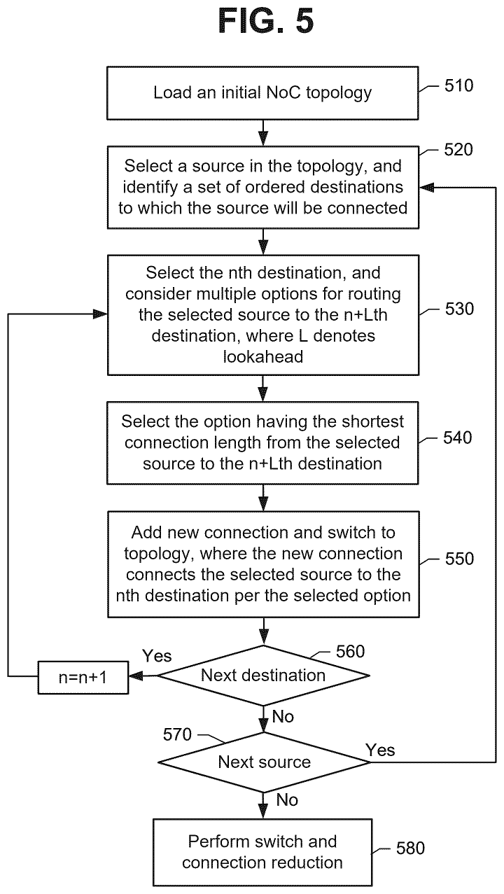

FIG. 5 illustrates another method of automatically generating a coarse-level NoC topology. Unlike the method of FIG. 3, the method of FIG. 5 considers not only the shortest valid path of a new connection being added, but it also looks ahead and considers how the new connection will affect at least one additional connection that will be added afterwards. There might be more than one option for adding an additional connection. Where there are multiple options, the method of FIG. 5 considers total valid connection length of each option, and selects the option having the shortest distance.

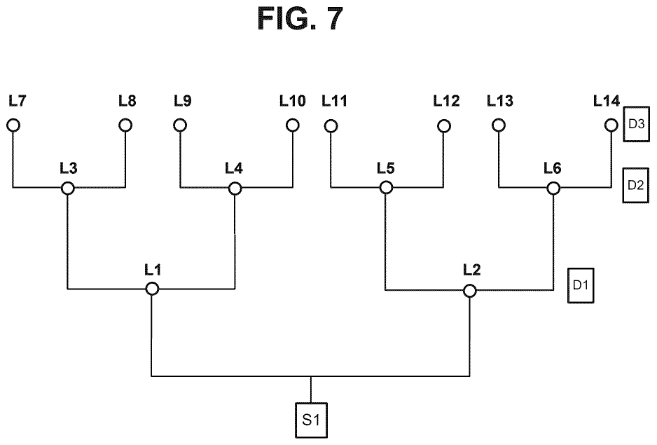

Before describing the method of FIG. 5, reference is made to FIG. 7, which illustrates a simple example of possible connections from a selected source S1 to each destination D1, D2, D3 in set D. Each connection is represented as a branch and has a valid connection length. In this simple example, there are two possible connections from the selected source to the first destination D1, two possible connections from the first destination D1 to the second destination D2 for each first-level branch, and two possible connections from the second destination D2 to the third destination D3 for each second-level branch. Thus, when looking at the possible paths that can be taken from the selected source S1, the system uses a forward looking approach from the selected source S1 that can consider all possible branches to the various destinations D1, D2, D3, and D4. This is referred to herein as lookahead and the number of branches or path options depend on how many steps or layers that are looked ahead. The lookahead may be a numerical representation of the number of destinations ahead of the selected source.

If no lookahead is performed, only two options L1 and L2 will be considered, and the option with the shortest valid connection length from the selected source S1 to the first destination D1 will be selected. If a lookahead of one is used, four options L3, L4, L5 and L6 will be considered, and the option with the shortest valid connection length from the selected source S1 to the second destination D2 will be selected. However, only the connection from S1 to D1 in the selected option will be added to the NoC topology.

If a lookahead of two is used, eight options L7, L8, L9, L10, L11, L12, L13 and L4 will be considered, and the option with the shortest valid connection length from S1 to D3 will be selected. However, only the connection from S1 to D1 in the selected option will be added to the NoC topology.

Reference is now made to FIG. 5. At block 510, an initial topology is loaded. At block 520, a source is selected, and a set D of ordered destinations is identified.

At block 530, the n^{th} destination is selected, and multiple options for routing the selected source to the n+L^{th} destination are considered, where L denotes the lookahead.

At block 540, the option having the shortest valid connection length from the selected source to the n+L^{th} destination is selected.

At block 550, a new connection is added to the topology. The new connection connects the selected source to the n^{th} destination per the selected option. If the new connection is from S1 to D1, the new connection will be made directly to the selected source S1 and the first destination D1. For all subsequent connections, the new connection will be made from the n^{th} destination to an existing connection in the topology. Any switches for connecting the new connection to an existing connection are also added to the topology.

At block 560, if there is another destination in set D, control is returned to block 530. Otherwise, control is sent to block 570.

At block 570, if there is another source to be selected, control is returned to block 520. Otherwise, switch and connection reduction may be performed at block 580.

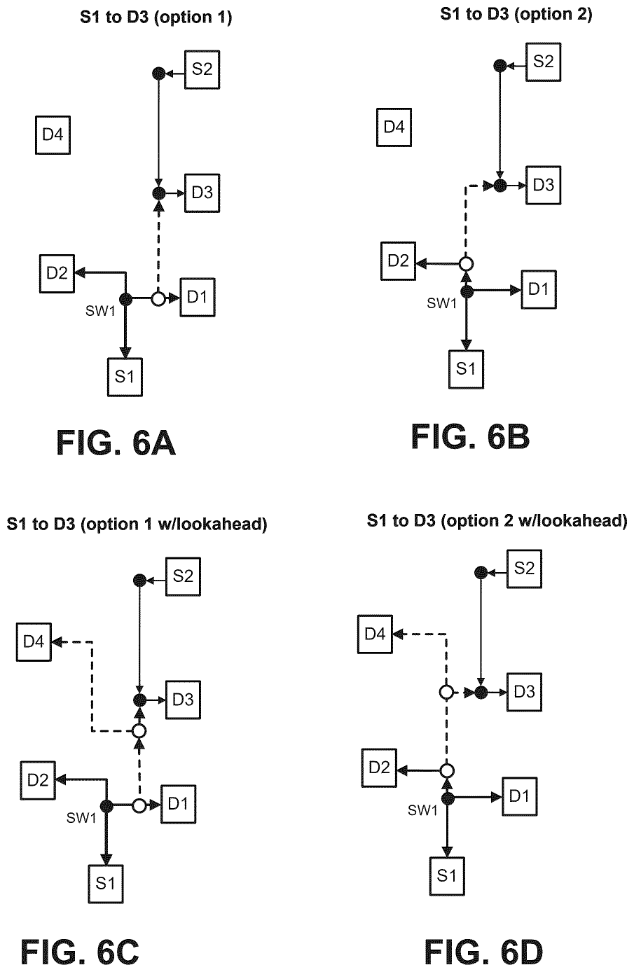

FIGS. 6A, 6B, 6C, and 6D illustrate a simple example that loads the topology of FIG. 4A and makes incremental modifications with a lookahead of L=1 according to the method of FIG. 5. First and second incremental modifications are made (but not shown) to connect the selected source S1 to the first and second destinations D1 and D2. FIGS. 6A to 6D will now illustrate a third incremental modification that connects the third destination with a lookahead of L=1.

FIGS. 6A and 6B shows first and second options, respectively, for connecting the third destination D3. The first option proposes the same route as FIG. 4C. The second option proposes a route that is closer to the fourth destination D4.

FIGS. 6C and 6D show the first and second options, respectively, with lookahead to the fourth destination D4. Possible connections to the fourth destination D4 are shown in dash. The connection to the fourth destination D4 in FIG. 6D (option 2) traverses a shorter distances than the connection to the fourth destination D4 in FIG. 6C (option 1). Therefore, the second option is selected. The connection to D3 from option 2 is added to the topology. A switch is also added to connect the new connection to the nearest existing connection.

The example of FIGS. 6A-6D illustrate a lookahead of one destination. However, the number of lookahead destinations is configurable. A larger number of lookahead destinations will have a greater number of options and will take longer to process for each incremental modification, but the resulting topology will likely be more accurate.

The methods of FIGS. 3 and 5 produce coarse-level topologies quickly and accurately without switch and connection reduction. However, accuracy may be further improved by removing at least some redundant switches and connections in accordance with the method of FIG. 8.

Reference is made to FIG. 8, which illustrates a method of removing redundant switches and redundant connections in a coarse-level topology. A first phase of the method includes identifying and removing short connections. A connection may be considered “short” if its length is less than a user-defined distance threshold.

The first phase is performed in blocks 810-850. At block 810, the coarse-level topology is examined to identify short connections between switches. At block 820, the next short connection is selected for removal. The selected short connection is between two switches.

At block 830, one of the two switches is selected to be removed, and the other of the two switches is selected to remain. Connections at egress ports of the removed switch are rerouted to egress ports of the remaining switch. Connections at ingress ports of the removed switch are rerouted to ingress ports of the remaining switch. A connection going from the removed switch to the remaining switch is rerouted to the remaining switch. This is done to preserve the number of connections and thereby keep dependencies between connections intact.

At block 840, the placement of the remaining switch is adjusted. A position that minimizes the length of all connections to the remaining switch is desirable.

If any other short connections are identified for removal (block 850), control is returned to block 820. Otherwise, a second phase of the reduction method is performed.

The second phase includes merging redundant connections. Redundancy could result from removing switches during the first phase. Redundant connections include connections that are routed from a switch to itself. Redundant connections also include multiple connections between the same two switches. For example, three segments going from a first switch to a second switch would be considered redundant.

The second phase is performed in blocks 860 and 870. During this second phase, no new connection dependencies are introduced, and it is ensured that no new deadlocks and no new traffic class (separation) violations are introduced. A traffic class refers to a way of physically separating certain traffic (source-destination pairs) from each other. When redundant connections are merged, traffics of two different traffic classes should not be merged.

At block 860, redundant connections are identified in the coarse-level topology and merged into a single connection. At block 870, connections going from a switch to itself may be eliminated.

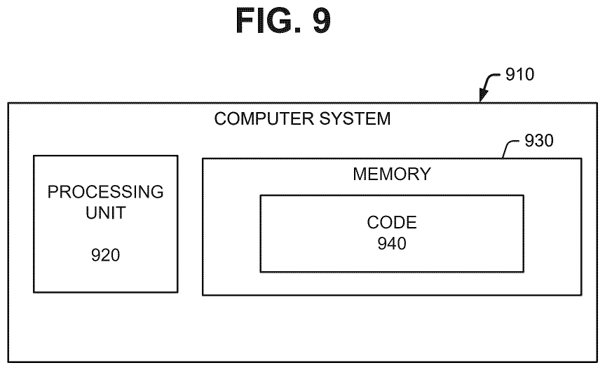

Reference is now made to FIG. 9, which illustrates elements of a computer system 910 including a processing unit 920 and computer-readable memory 930 encoded with code 940 that, when executed, causes the computer system 910 to generate a coarse-level topology according to a method herein. In some embodiments, the code 940 may be part of a standalone application, such as an electronic computer aided (ECAD) design tool. In some embodiments, the code 940 may be integrated into a larger program that also performs one or more of blocks 210-240 of FIG. 2.

The methods above incorporate an algorithmic approach towards incrementally generating a coarse-level topology of a NoC. In the alternative, a trained machine learning model may be used to incrementally generate a coarse-level NoC topology.

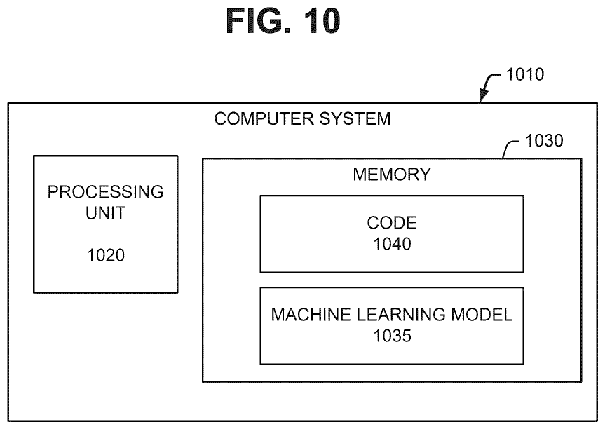

FIG. 10 illustrates elements of a computer system 1010 including a processing unit 1020 and computer-readable memory 1030 encoded with a trained machine learning model (or large language model) 1035 and code 1040 that, when executed, causes the computer system 1010 to start with an initial NoC topology including ports for sources and destinations, and synthesize a coarse-level NoC topology by incrementally adding connections until each source is connected to its corresponding set of destinations, where the connections are subject to routing constraints (e.g., blockages).

In some embodiments, the machine learning model 1035 may include a transformer model. A transformer model is a type of neural network architecture that excels at processing sequential data. The transformer model has an attention mechanism that can discern long-range dependencies, such as correlations between text in files and pixels in images that aren't neighboring one another. In general, an attention mechanism reads raw data sequences and converts the sequences into vector embeddings, determines similarities, correlations and other dependencies (or lack thereof) between each vector and each other vector, and generates attention weights (e.g., using query, key and value vectors). The attention weights are used to emphasize or deemphasize the influence of specific input elements at specific times.

The machine learning model 1035 is not limited to a transformer model. Other embodiments may be based on other types of machine learning models including, but not limited to long-short term memory and recurrent neural networks (RNNs). RNNs utilize recurrent connections, where the output of a neuron at one time step is fed back as input to the network at the next time step. This enables RNNs to capture temporal dependencies and patterns within sequences.

In the embodiment shown in FIG. 10, the machine learning model 1035 resides in the computer system 1010. In other embodiments, the machine learning model 1035 may be at a remote location that is accessible to the computer system 1010.

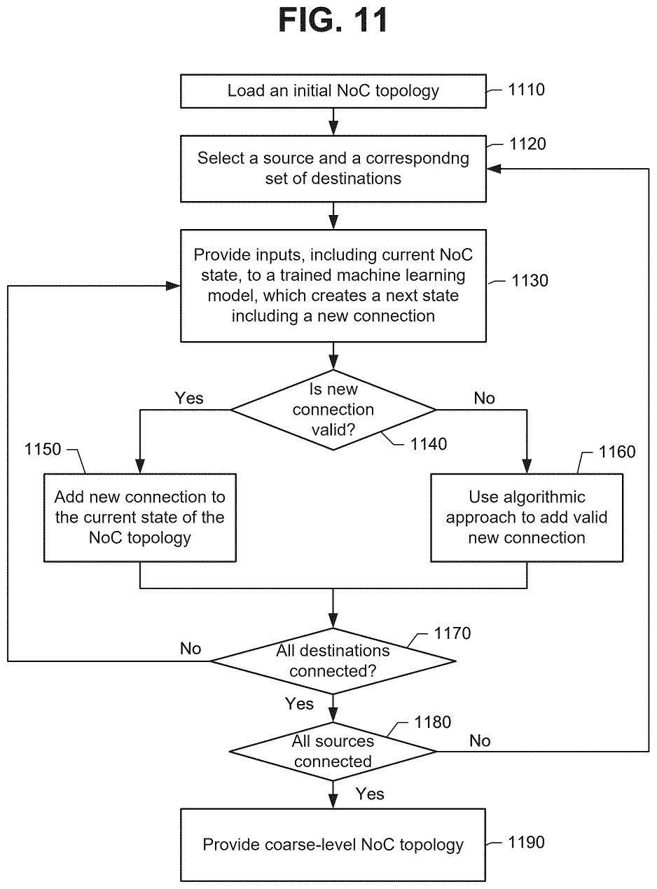

Reference is now made to FIG. 11, which illustrates a method of synthesizing a NoC topology using the trained machine learning model. At block 1110, an initial topology is loaded. At block 1120, a source and a corresponding set of destinations is selected.

At block 1130, inputs are provided to the trained machine learning model, including the selected source and a set of destinations, and the current state of the NoC topology, physical placements, etc. In response, the trained machine learning model transforms the current state by suggesting a new state including a new connection.

In some embodiments, the state includes an image and text. The image contains blockages positions and dimensions. The text describes positions, dimensions and parameters of devices (sources, targets and interconnect elements), and routes. The routes may have the following form: <initiator> [list of interconnect elements] <target>.

At block 1140, it is determined whether the new connection is valid. The new connection is considered valid if it follows constraints, is deadlock free, etc. If the new connection is valid, it is added to the current state of the NoC topology (block 1150).

If the new connection is not valid, an algorithmic approach may be used to add a new valid connection (e.g., the method of FIG. 3 or 5) (block 1160). Falling back to an algorithmic approach enables the transformer-based method to remain resilient to any mistakes made by the transformer model.

Connections are added until the selected source is connected to its set of destinations (block 1170). Then control is returned to block 1130, where a new source and corresponding set of destinations are selected. After all selected sources have been connected to their corresponding destinations (block 1180), a coarse-level topology is provided (block 1190).

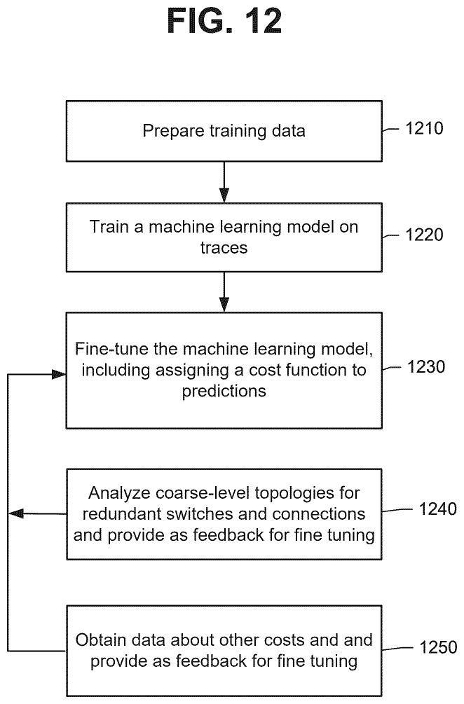

Reference is now made to FIG. 12, which illustrates a method of training a machine learning model to synthesize a coarse-level NoC topology. At block 1210, training data is prepared. The machine learning model may be trained on training data including traces of prior topology synthesis, preferably from real designs. The traces describe intermediate states of a NoC after each connection is routed. The traces may include relevant input information, constraint, physical data, tuning parameters, etc. Randomized algorithm executions with various input parameters may be performed to generate a large variety of traces under different kinds of NoC designs.

At block 1220, the transformer model is trained on these traces. The traces cause the machine learning model to learn to predict the next state of the NoC given its current state. At this stage of training, the machine learning model is not aware of which choices are good and which choices are bad.

At block 1230, the machine learning model may then be fine-tuned by having it predict transformations and this time, assigning a cost function to the predictions. The cost function may be based, for example, on wire length, and route deviation. The cost function may also be based on redundant switches and redundant connections. The fine-tuning teaches the machine learning model to recognize choices that are good, such as minimizing wire length and route deviation, and avoiding redundant switches and connections.

In some embodiments, a machine learning model may be trained on a large corpus of data to make incremental connections. The process of fine-tuning the machine learning model may then involve unfreezing some or all of the layers of the pre-trained model and training them on the new training data using a specific cost function. The remaining layers can be kept frozen, preserving the pre-learned representations. This approach advantageously allows different coarse-level topologies to be generated with respect to different costs. As a first example, the fine-tuning is performed with respect to redundancy only. As a second example, other costs are brought in, such as wire length and latency.

At blocks 1240 and 1250, feedback may be obtained and used to adjust fine-tuning. At block 1240, coarse-level topologies produced by methods herein are analyzed for redundant switches and redundant connections. The method of FIG. 8 may be used to identify those switches and connections that are redundant, and those redundant switches and redundant connections that are removed. Redundant switches and redundant connections may be assigned penalties, and removed switches and connections may be assigned even higher penalties.

Redundant switches and redundant connections increase area and can increase latency. Reducing the number of redundant switches and redundant connections. can reduce chip area and increase chip speed.

At block 1250, data about other costs (e.g., wire length, latency, route deviation) may be obtained. The data may be synthesized and/or real. Synthesized data may be obtained, for example, by running simulations of NoCs. Real data may be obtained by taking measurements of fabricated NoCs.

Certain methods, which can be implemented in a product, according to the various aspects of the invention may be performed by instructions that are stored upon a non-transitory computer readable medium. The non-transitory computer readable medium stores code including instructions that, if executed by one or more processors, would cause a system or computer to perform steps of the method described herein. The non-transitory computer readable medium includes: a rotating magnetic disk, a rotating optical disk, a flash random access memory (RAM) chip, and other mechanically moving or solid-state storage media. Any type of computer-readable medium is appropriate for storing code comprising instructions according to various example.

Some examples are one or more non-transitory computer readable media arranged to store such instructions for methods described herein. Whatever machine holds non-transitory computer readable media comprising any of the necessary code may implement an example. Some examples may be implemented as: physical devices such as semiconductor chips; hardware description language representations of the logical or functional behavior of such devices; and one or more non-transitory computer readable media arranged to store such hardware description language representations.

Certain examples have been described herein and it will be noted that different combinations of different components from different examples may be possible. Salient features are presented to better explain examples; however, it is clear that certain features may be added, modified and/or omitted without modifying the functional aspects of these examples as described.

Various examples are methods that use the behavior of either or a combination of machines. Method examples are complete wherever in the world most constituent steps occur. For example, IP elements or units include: processors (e.g., CPUs or GPUs), random-access memory (RAM—e.g., off-chip dynamic RAM or DRAM), a network interface for wired or wireless connections such as ethernet, WiFi, 3G, 4G long-term evolution (LTE), 5G, and other wireless interface standard radios. The IP may also include various I/O interface devices, as needed for different peripheral devices such as touch screen sensors, geolocation receivers, microphones, speakers, Bluetooth peripherals, and USB devices, such as keyboards and mice, among others. By executing instructions stored in RAM devices processors perform steps of methods as described herein.

Descriptions herein reciting principles, aspects, and embodiments encompass both structural and functional equivalents thereof. Elements described herein as coupled have an effectual relationship realizable by a direct connection or indirectly with one or more other intervening elements.

Practitioners skilled in the art will recognize many modifications and variations. The modifications and variations include any relevant combination of the disclosed features. Descriptions herein reciting principles, aspects, and embodiments encompass both structural and functional equivalents thereof. Elements described herein as “coupled” or “communicatively coupled” have an effectual relationship realizable by a direct connection or indirect connection, which uses one or more other intervening elements. Embodiments described herein as “communicating” or “in communication with” another device, module, or elements include any form of communication or link and include an effectual relationship. For example, a communication link may be established using a wired connection, wireless protocols, near-filed protocols, or RFID.

To the extent that the terms “including”, “includes”, “having”, “has”, “with”, or variants thereof are used in either the detailed description and the claims, such terms are intended to be inclusive in a similar manner to the term “comprising.”

The scope of the invention, therefore, is not intended to be limited to the exemplary embodiments shown and described herein. Rather, the scope and spirit of present invention is embodied by the appended claims.

What is claimed is:

1. A computer system comprising:
a processing unit; and
computer memory that stored code, which when executed by the processing unit, causes the computer system to:
select a source and a set of destinations in a network-on-chip (NoC) topology; and
incrementally add new connections to the NoC topology, one connection at a time until the source is connected to the destinations;
wherein adding a new connection includes:
using a trained machine learning model to receive a current state of the NoC topology and suggest a new state including a new connection; and
adding the new connection to the current state if the new connection is valid.

2. The computer system of claim 1, wherein the current state is fed back to the machine learning model, which then generates a new state including a new connection.

3. The computer system of claim 1, wherein the code, when executed, further causes the computer system to use the machine learning model to incrementally add new connections to the NoC topology to connect any additional sources to their corresponding destinations until a coarse-level topology is produced.

4. The computer system of claim 3, wherein the code, when executed by the processing unit, further causes the computer system to identify redundant switches and redundant connections in the coarse-level topology.

5. The computer system of claim 4, wherein the code, when executed by the processing unit, further causes the computer system to remove at least some of the redundant switches and the redundant connections in the coarse-level NoC topology.

6. The computer system of claim 5, wherein the code, when executed by the processing unit, further causes the computer system to use the identified redundant switches and redundant connections as feedback to fine-tune the machine learning model.

7. The computer system of claim 6, wherein the machine learning model is fine-tuned with respect to a cost function that penalizes for redundant switches and redundant connections.

8. The computer system of claim 5, wherein the code, when executed by the processing unit, further causes the computer system to:
process the coarse-level NoC topology to produce a final NoC topology; and
generate a register-transfer level (RTL) description of the final NoC topology.

9. The computer system of claim 1, wherein the code is part of a NoC design tool.

10. A computer-implemented method of network-on-chip (NoC) synthesis, the method comprising:
using a trained machine learning model to generate a coarse-level NoC topology, including incrementally adding new connections to the coarse-level NoC topology until at least one source is connected to a corresponding set of destinations; wherein the machine learning model is trained to receive a current state of the NoC topology and generate a new state including a new connection;
identifying redundant switches and redundant connections in the coarse-level NoC topology; and
using the identified switches and identified connections as feedback to fine-tune the machine learning model.

11. The computer-implemented method of claim 10, wherein the machine learning model is fine-tuned with respect to a cost function that penalizes for redundant switches and redundant connections.

12. The computer-implemented method of claim 10, wherein identifying the redundant switches and the redundant connections includes:
examining traces to identify short connections between switches; and
rerouting at least some of the short connections, wherein rerouting a short connection between a pair of switches includes removing one of the switches in the pair (the removed switch) and rerouting connections at the removed switch in the pair to another of the switches in the pair (a remaining switch).

13. The computer-implemented method of claim 10, further comprising training the machine learning model on training data including traces of prior topology synthesis, wherein the traces describe intermediate states of a NoC after each connection is routed.

14. The computer-implemented method of claim 13, further comprising generating the traces, including generating randomized algorithm executions with various input parameters to produce a variety of traces for different NoC designs.

15. A computer-implemented method of designing a network-on-chip (NoC), the method comprising:
accessing a multitude of traces generated for different NoC designs, wherein each trace describes an intermediate state of a NoC topology after a new connection from a source to a destination is added;
identifying redundant switches and redundant connections in the traces and tagging the redundant switches and the redundant connections in the traces; and
training a machine learning model on the traces to predict a next state of a NoC topology given a current state of the NoC topology, such that the next state avoids redundant switches and redundant connections.

16. The computer-implemented method of claim 15, wherein each next state includes the current state and at least one new connection to a destination.

17. The computer-implemented method of claim 15, wherein the machine learning model includes a transformer model that is fine-tuned with a cost function that penalizes redundant switches and redundant connections.

18. The computer-implemented method of claim 17, wherein the cost function is also based on wire length and/or route deviation.

19. The computer-implemented method of claim 15, wherein identifying the redundant switches and the redundant connections includes:
examining the traces to identify short connections between switches; and
rerouting at least some of the short connections, wherein rerouting a short connection between a pair of switches includes removing one of the switches in the pair (the removed switch) and rerouting connections at the removed switch in the pair to another of the switches in the pair (a remaining switch).

20. The computer-implemented method of claim 15, wherein accessing the multitude of traces includes generating randomized algorithm executions with various input parameters to produce traces for different NoC designs.
